(19) United States
(12) Patent Application Publication
(10) Pub. No.: US 2005/0225332 A1
(43) Pub. Date: Oct. 13, 2005

(54) Resonator housing for microwaves

(75) Inventor: Dierk Schroder, Hamburg (DE)

Correspondence Address: VENABLE LLP, P.O. BOX 34385, WASHINGTON, DC, 20045-9998, US

(73) Assignee: HAUNI Maschinenbau AG, Hamburg (DE)

(21) Appl. No.: 11/090,688

(22) Filed: Mar. 28, 2005

(30) Foreign Application Priority Data
Apr. 7, 2004 (DE) 10 2004 017 597.7

(51) Int. Cl. H01P 1/20; G01R 27/04; G01R 27/32

(52) U.S. Cl. 324/636

(57) ABSTRACT

The invention relates to a resonator housing for detecting at least one characteristic of a strand of the tobacco processing industry. Moreover the invention relates to the use of a material for one part of a resonator housing. The invention resides in the provision that the part of the housing, which substantially determines the shape of the resonator, comprises, at least in part, a non-metallic material.

### CROSS-REFERENCE TO RELATED APPLICATION

This application claims the priority of German Patent Application No. 10 2004 017 597.7 filed Apr. 7, 2004. The disclosure of the foreign priority application and the disclosures of each U.S. and foreign patent and patent application mentioned below are incorporated herein by reference.

### BACKGROUND OF THE INVENTION

The present invention relates to a resonator housing for detecting at least one characteristic of a strand of the tobacco processing industry. Finally, the invention relates to the use of a material for one part of a resonator housing.

The term “strand of the tobacco processing industry” denotes a wrapped or non-wrapped strand of smokeable material such as cut tobacco, cigarillo tobacco, cigar tobacco or any other material adapted for being smoked; this term may also denote a strand of a filter material such as cellulose acetate or paper.

Documents such as the European Patent Application EP 0 791 823 A2 disclose that for the detection of the mass and/or the humidity of a tobacco strand, particularly a cigarette strand consisting of cut tobacco wrapped into cigarette paper, the strand is passed through a measuring chamber (hereinafter referred to as “resonator housing”) made of metallic material where the strand is exposed to microwaves. With application of special analyzer circuits, it is possible to conclude, for example, the mass and/or the humidity per unit length of the strand from variations of characteristic values of the supplied microwaves with a strand passing through the resonator housing and with an empty resonator housing, for instance, or in relation to standard values.

It is known from the German Patent Application DE 198 54 550 A1 that a resonator housing of metallic material consists, at least in parts, of a material displaying a small coefficient of thermal expansion. The coefficient of thermal expansion a indicates the specific fraction of the overall length, by which a material expands when it is heated by one Kelvin (K).

An alloy containing approximately 64% of iron and approximately 36% of nickel is indicated as a preferred embodiment. At room temperature, this alloy, which is also referred to as “INVAR”, has a coefficient of thermal expansion α of 10⁻⁶ K⁻¹ approximately. This means that a piece of the material, which presents a length of one meter in one direction, expands by one micrometer (10⁻⁶ m) when the temperature is increased by one Kelvin. Typical coefficients of thermal expansion of metals such as iron exceed the co-efficient of INVAR by a factor of ten.

For a further increase of the stability of the dimensions of the resonator cavity the German Patent Application DE 198 54 550 A1 indicates furthermore that the resonator housing comprises a temperature controlling system that maintains its operating temperature at least approximately constant.

### SUMMARY OF THE INVENTION

It is the object of the present invention to provide a resonator housing with a high measuring accuracy and/or sensitivity in measurement.

The object is attained according to the invention by providing that the part of the housing, which substantially determines the shape of the resonator, comprises, at least in parts, a non-metallic material.

The part of the housing substantially determining the shape of the resonator includes the components that support or form the resonator wall in a two-dimensional manner. Antennas that serve to couple the microwaves into the resonator and to decouple them from the resonator and possibly existing insulating rings surrounding the antennas, which serve to insulate the antennas from the housing and from the resonator wall, do not form part of the housing in the sense of the invention.

In distinction from metallic materials, the term “non-metallic materials” is meant to denote particularly non-metallic materials such as ceramics, synthetic materials, glasses and glass-ceramics. These materials are not defined as metallic materials even in the presence of metal atoms provided e.g. by doping or addition, because the presence of the metal atoms does not give them all the properties of metals. However, the doping of the materials, even with non-metal atoms, ions or molecules, may result in an electrically conductive non-metallic material.

In the sense of the invention one has to distinguish between a resonator housing and a resonator. A resonator is a cavity (resonator cavity) that is limited, at least in parts, by an electrically conductive material (resonator wall). Electromagnetic waves passed into the resonator cavity are reflected on the electrically conductive resonator wall and may superimpose each other in a constructive (amplifying) or destructive (weakening) manner in correspondence with the resonance characteristics of the resonator, which depend on the frequency of the electromagnetic waves. The dependence of resonance from frequency results in a characteristic resonance curve which depends on the shape of the resonator cavity, on the materials used for the resonator walls and on further material in the resonator cavity.

The poorer the electric conductivity of the wall material is, the weaker is the reflection of the electromagnetic waves and the weaker the resonance may build up. In the presence of material in the resonator cavity, one part of the electromagnetic waves is absorbed so that the resonance is equally weakened or that the resonance frequency is shifted. Furthermore, a variation of the shape of the resonator will result in a variation of the frequency development of the resonance curve.

The resonator housing, by contrast, surrounds the resonator or the resonator cavity, respectively, and defines its form. When the resonator housing as such is made of an electrically conductive material the inner wall of the housing, which encloses the resonator, may be considered as resonator wall forming part of the resonator, as will be explained in more details in the following.

Due to the skin effect occurring at high frequencies of electromagnetic waves, microwaves penetrate into the resonator wall only to a depth of a few micrometers. In the material beyond this thin layer of a few micrometers it is irrelevant for the creation of resonance in the resonator whether the material is electrically conductive.

Depending on the properties of the material or the materials of which the resonator housing is made, it may be sensible or necessary to coat the inner surface of the resonator housing, which encloses the resonator, with a conductive and in particular corrosion resistant material. In this case, only the coating should be considered as resonator wall. In such a case, the resonator housing serves only as supporting housing of a resonator not supporting itself.

As the resonance of the microwaves passed into the resonator is sensitively dependent on the shape and on the dimensions of the resonator cavity it is important to maintain the shape and the dimensions of the resonator constant, independently of influences from the surroundings, e.g. the temperature.

Those parts of the resonator housing, which determine the shape of the resonator cavity, are expediently composed of the non-metallic material having a small coefficient of expansion. Hence, dimensioning and the shape of the resonator cavity are largely independent of the ambient temperature. As a result, a largely constant amplitude and shape of the characteristic resonance curve of the resonator cavity for microwaves are ensured and the requirement of a constant reference measure is satisfied for the measurement. The coefficient of thermal expansion of the non-metallic material is preferably smaller than 10⁻⁶ K⁻¹ at least within a temperature range from 20° C. to 40° C.

Suitable non-metallic materials having a small coefficient of thermal expansion are known. Some special glass-ceramics and glass types whose manufacturing processes are optimized specifically for the achievement of a small coefficient of thermal expansion should be mentioned here by way of example.

The glass-ceramic material Zerodur® of the company of Schott Glas, Mainz, displays a mean coefficient of thermal expansion of 0+0.1·10⁻⁶ K⁻¹ or better in the temperature range between 0° C. and 50° C., which means that a thermal (quasi) zero expansion is achieved with a manufacturing tolerance of 0.1·10−6 K⁻¹. The basic material for such a glass-ceramic material is a glass block that is heated by a ceramizing process and then cooled again in a controlled manner. With the controlled cooling a crystalline phase is grown, in addition to the amorphous glass phase typical of glass, which accounts for 70 to 78 percent by weight of the material. The coefficients of thermal expansion of the two phases are opposite to each other. This means that one phase expands when the material is heated whereas the other one contracts. The parts by weight of the two phases in the material are selected such that the opposite coefficient of thermal expansion of the crystalline phase and of the amorphous glass phase balance each other in total so that the result is a thermal (quasi) zero expansion. The mechanical properties and the machinability of the material correspond to the values of glass.

The material ULE® of Corning Inc., New York, is a glass having a mean coefficient of thermal expansion of 0+0.03·10⁻⁶ K⁻¹. This material is deposited on a sand substrate in a flame hydrolysis process. In that process, in essence, quartz glass is evaporated and titanium ions are added to the flame. The deposited substrate is substantially a glass doped with titanium ions. In that case, the admixture of titanium ions accounts for the zero expansion.

The listed materials have been mentioned, without any restriction of the materials within the scope of the invention, as representative of non-metallic materials having a small coefficient of thermal expansion.

The coefficient of thermal expansion of a material having a very low value of α is expediently measured by interferometry on material measures, e.g. spherical interferometry, plane-face interferometry or high-precision interferometry. These measuring methods, which are applied at the Physikalisch-Technische Bundesanstalt in Braunschweig, Germany, for instance, are suitable for both metallic and non-metallic materials.

According to an advantageous embodiment it is provided that the part of the housing, which substantially determines the shape of the resonator, comprises, at least in parts, a glass-ceramic material. It is equally advantageous that the part of the housing, which substantially determines the shape of the resonator, comprises, at least in parts, a glass material. In this context, the terms glass-ceramic material or a glass material is meant to denote materials having a particularly small coefficient of thermal expansion. When a material with such a small coefficient of thermal expansion is used it is no longer necessary to provide a temperature controlling system. At operating temperatures from room temperature up to roughly 40° C., a constancy of the resonator geometry is ensured, which satisfies the requirements in terms of accuracy in measurement. It is preferably not necessary to provide a temperature controlling system.

Regarding the configuration of the resonator housing, one development provides for the resonator cavity having the shape of a symmetrical hollow body. It is advantageous for the generation of a microwave resonance field as homogeneous as possible that the resonator cavity presents, at least in sections, the shape of a rotationally symmetrical hollow body, preferably a hollow cylinder. When the axis of symmetry of the hollow body is oriented along the conveying direction of the object to be measured, in particular, a resonance mode can be achieved that displays a particularly high field strength at the site of the object to be measured.

The shape of the resonator cavity may vary from the precise shape of a hollow cylinder. In such a case, an at least approximately symmetrical shape, e.g. a polygonal shape, is also advantageous.

One expedient embodiment of the resonator housing consists in the aspect that a closing element for closing the interior space of the resonator housing is comprised by the resonator housing. The closing element can be expediently removed and mounted again in operation so that the interior space of the resonator housing can be maintained and cleaned.

One advantageous embodiment of the resonator housing consists in the provision that the surfaces of the resonator housing, which define the resonator, are coated, at least in parts, with a corrosion resistant material having a high electric conductivity. This may be sensible in the case of some non-metallic materials as a component of the resonator housing because in the event of high-frequency electromagnetic alternating fields, e.g. with microwaves impinging on the interface of a material, the reflection of the electromagnetic waves is attenuated by the occurrence of the skin effect.

For compensation of this effect the surface of the interior space of the resonator is coated with a material having a high electrical conductivity. According to the invention, a high electrical conductivity should be understood to be in the order of roughly 10·10⁶ S/m or more. Examples of materials having a high electrical conductivity are gold (42·10⁶ S/m), copper (60·10⁶ S/m) and silver (63·10⁶ S/m).

For the sake of a long-term stability of the results of measurement, which is in particular due to the stability of the shape and the dimensions of the resonator cavity, it is advantageous that the electrical conductivity of the coating material will not vary in the course of time. To this end a corrosion resistant material is provided.

A particularly advantageous embodiment provides that the material used for the coating is comprised substantially of gold or at least contains gold. Conductive synthetic materials are equally known which are highly corrosion resistant, too. These synthetic materials also come into consideration for coating.

Non-metallic materials are known, too, which are electrically conductive or become electrically conductive, e.g. by doping. It is therefore preferably provided that the non-metallic material is electrically conductive.

An advantageous configuration of the resonator housing consists in the provision that it is comprised entirely of the non-metallic material in order to keep mechanical strain low, which is due to the use of materials having different coefficients of thermal expansion. With this provision one achieves the effect that a thermal expansion or contraction of another component of the resonator housing will not take an influence on the shape of the resonator.

The object of the invention is moreover attained by a measuring apparatus including a resonator housing, wherein the resonator housing is configured in the manner described above.

The object of the invention is also attained by the use of a non-metallic material having a coefficient of thermal expansion that is lower than 10⁻⁶ K⁻¹, at least within a temperature range from 20° C. to 40° C., for at least one part of the section of a resonator housing, which substantially determines the shape of the resonator, for detection, without temperature control, of at least one property of a strand of the tobacco processing industry. A resonator housing made of the aforedescribed material ensures stability of the resonator cavity in terms of shape and size in the indicated temperature range, which ensures a high reproducibility of the results of measurement.

According to another advantageous configuration of the invention, a protective tube surrounding the strand is provided. The protective tube advantageously consists of a synthetic material, at least in parts, particularly of a material from the polyarylether group (PAEK group), specifically polyetheretherketone (PEEK). The protective tube according to the invention may be widened in the strand entry zone.

In accordance with the invention, the resonator housing may be prolonged outside the interior space (resonator cavity) to the outside along the direction of the strand in order to prevent the emission of microwaves.

The resonator housing may also be prolonged inside the resonator cavity towards the inside along the direction of the strand. The invention offers numerous advantages:

The resonator housing and the resonator cavity of non-metallic material having an extremely or very small coefficient of thermal expansion changes its shape only very slightly when the temperature changes. The consequence is a very good constancy of the resonator characteristics, which is a benefit to the precision and constancy of the acquisition of the measured values.

The use of corrosion resistant material such as gold for the coating of the resonator cavity prevents corrosion and changes of the resonator characteristics, which are caused by corrosion. On account of the good electrical conductivity of this coating material negative influences due to the so-called skin effect are largely kept at a very low level.

The resonator housing is particularly well suited for the supply of microwaves and the conversion of the microwave signals into measuring signals according to the invention.

The object of the invention is also attained by a method for measuring at least one property of a strand of the tobacco processing industry without temperature control, the method comprising the steps of:
feeding microwaves into a resonating cavity of a resonator situated in a resonator housing of non-metallic material having a coefficient of thermal expansion that is lower than 10⁻⁶ K⁻¹, at least within a temperature range from 20° C. to 40° C., for at least one part of the section of said resonator housing, which substantially determines the shape of the resonator;
feeding a strand of the tobacco processing industry into said measuring apparatus;
analyzing the resonance of microwaves in the resonating cavity.

With this method it is possible to measure at least one property of a strand of the tobacco processing industry in a temperature independent manner, while there is no need for temperature control.

The term “analyzing” is meant to denote the measurement of the strength of the microwave resonance inside the resonating cavity and of its change at one or more frequencies according to the presence and consistency of a strand of the tobacco processing industry inside the cavity.

### BRIEF DESCRIPTION OF THE DRAWINGS

The invention is explained in the following with the aid of the exemplary embodiments shown in the drawings and is described without restricting the general inventive idea, wherein for all inventive details not described further in the text may be discerned from the drawings.

FIG. 1 is a schematic illustration of a resonator housing.

### DETAILED DESCRIPTION OF THE INVENTION

In the following drawings, the same or similar elements or parts are given the same reference numbers and will not be introduced again.

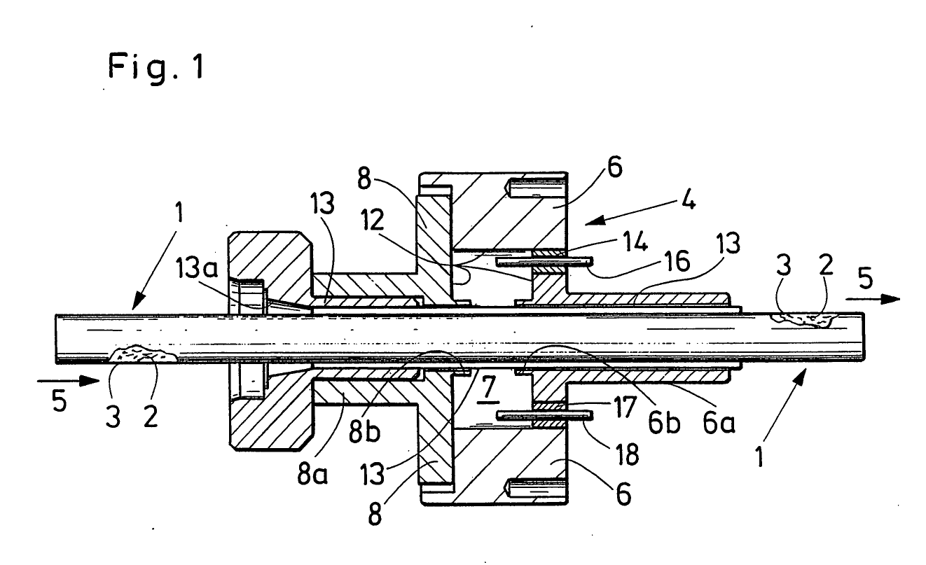

FIG. 1 illustrates a partly broken-up cigarette strand 1 moved along the direction of the arrow 5, which consists of a filler 2 of cut tobacco and a tubular envelope 3 made of cigarette paper and which passes through a resonator housing 4 to which microwaves are supplied for detecting at least one property of the filler 2, for instance the mass or the humidity. The resonator housing 4 comprises a hollow body in the form of a hollow cylinder 6 whose interior space (resonator cavity) 7 is arranged symmetrically to the cigarette strand 1. A cover 8 is screwed to the housing for closure. Both the hollow cylinder 6 and the cover 8 comprise a non-metallic material having a very small coefficient of thermal expansion, for instance a glass or glass-ceramics material. At least the hollow cylinder 6 should be made of the non-metallic material having a very small coefficient of thermal expansion. Due to the good constancy of the geometry of the resonator housing 4 and the resonator cavity 7 one can also achieve a proper constancy of the results of measurement.

A thin gold layer 12 is vapor deposited on the resonator cavity 7 of the resonator housing 4, which reliably prevents the occurrence of corrosion that could affect the constancy of the results of measurement while it limits, at the same time, a detrimental skin effect because it is a good electrical conductor.

A protective tube 13, which is advantageously made of a substance from the polyaryletherketone (PAEK) group, e.g. polyetheretherketone (PEEK), serves for mechanically closing the resonator cavity 7 from the cigarette strand 1 and from contaminating particles possibly conveyed by the strand 1, i.e. for preventing the resonator cavity 7 from soiling that would impair the result of measurement. The protective tube 13 flares in a funnel-shape at one of its ends 13a where the strand 1 enters the resonator housing 6.

Outside of the resonator cavity 7, the resonator housing 4 extends in a tubular shape (6a, 8a) on both sides along the direction of the strand 1 towards the outside in order to prevent microwaves from being emitted from the resonator chamber. It extends also slightly inwards in a tubular shape (6b, 8b). An antenna 16 insulated from the hollow cylinder 6 by means of an insulating ring 14 serves to couple in the microwaves generated by a microwave generator. An antenna 18 insulated from the hollow cylinder 6 by an insulator 17 serves to decouple microwaves, which are to be supplied to an analyzer circuit which is not illustrated. A suitable analyzer circuit is disclosed in the German Patent Application DE 197 34 978.1.

It is possible to do without the insulating means 14 and 17 if the hollow cylinder 6 as such is not conductive. When a conductive non-metallic material is provided in the hollow cylinder 6 the insulating rings or insulation 14 and 17, respectively, are not required for the coupling antennas 16 and 18.

The invention has been described in detail with respect to preferred embodiments, and it will now be apparent from the foregoing to those skilled in the art, that changes and modifications may be made without departing from the invention in its broader aspects, and the invention, therefore, as defined in the appended claims, is intended tended to cover all such changes and modifications that fall within the true spirit of the invention.

1. A resonator housing for detecting at least one characteristic of a strand of the tobacco-processing industry, characterized in that the part of the housing, which substantially determines the shape of the resonator, comprises, at least in part, a non-metallic material.

2. The resonator housing according to claim 1, characterized in that the part of the housing, which substantially determines the shape of the resonator, has a coefficient of thermal expansion that is smaller than 10⁻⁶ K⁻¹ at least within a temperature range from 20° C. to 40° C.

3. The resonator housing according to claim 1, characterized in that the part of the housing, which substantially determines the shape of the resonator, comprises, at least in part, a glass-ceramic material.

4. The resonator housing according to claim 1, characterized in that the part of the housing, which substantially determines the shape of the resonator, comprises, at least in part, a glass material.

5. The resonator housing according to claim 1, characterized in that the resonator cavity has the shape of a symmetrical hollow body, at least in sections.

6. The resonator housing according to claim 1, characterized in that the surfaces of said resonator housing, which define the resonator, are coated, at least in part, with a corrosion resistant material having a high electrical conductivity.

7. The resonator housing according to claim 6, characterized in that the material used for coating contains gold.

8. The resonator housing according to claim 7, characterized in that the material used for coating is comprised substantially of gold.

9. The resonator housing according to claim 1, characterized in that the non-metallic material is electrically conductive.

10. The resonator housing according to claim 1, characterized in that it is comprised substantially entirely of the non-metallic material.

11. A measuring apparatus including a resonator housing according to claim 1.

12. A method for measuring at least one property of a strand of the tobacco processing industry without temperature control, the method comprising the steps of:
feeding microwaves into a resonating cavity of a resonator situated in a resonator housing of non-metallic material having a coefficient of thermal expansion that is lower than 10⁻⁶ K⁻¹, at least within a temperature range from 20° C. to 40° C., for at least one part of the section of said resonator housing, which substantially determines the shape of the resonator;
feeding a strand of the tobacco processing industry into said measuring apparatus;
analyzing the resonance of microwaves in the resonating cavity.
